(19) United States
(12) Patent Application Publication
(10) Pub. No.: US 2008/0116954 A1
(43) Pub. Date: May 22, 2008

(54) LEVEL SHIFTER WITH SPEEDY OPERATION

(75) Inventors: KAI-PING LIN, Hsinchu (TW); WEI-TE LAI, Hsinchu (TW); TSUNG-JEN LIN, Hsinchu (TW)

Correspondence Address: PCE INDUSTRY, INC.;ATT. CHENG-JU CHIANG, 458 E. LAMBERT ROAD, FULLERTON, CA, 92835, US

(73) Assignee: FITIPOWER INTEGRATED TECHNOLOGY, INC, Hsinchu (TW)

(21) Appl. No.: 11/733,168

(22) Filed: Apr. 9, 2007

(30) Foreign Application Priority Data
Nov. 17, 2006 (TW) 095142693

(51) Int. Cl. H03L 5/00

(52) U.S. Cl. 327/333

(57) ABSTRACT

A level shifter (100) includes a first transistor (111), a second transistor (112), a third transistor (121), a fourth transistor (122), a fifth transistor (151), and a sixth transistor (152). The first and second transistors are first-type transistors; and the third and fourth transistors are second-type transistors different from the first-type transistors. The fifth and sixth transistors are the first-type transistors same as the first and second transistors. The level shifter has a quick operating speed.

### BACKGROUND OF THE INVENTION

1. Field of the Invention

The present invention relates to level shifter for controlling voltage level and, more particularly, to a level shifter having a high operating speed.

2. Description of Related Art

As technology advances, the need for flat panel display such as liquid crystal displays (LCDs) is becoming increasingly popular. As a consequence, thin film transistor liquid crystal displays (TFT-LCDs) are widely used because of their excellent performance, large-scale information display capability, low power consumption, long lifetime, environmentally friendly disposition, etc. Generally, TFT-LCDs has a driving circuit to scan the thin film transistor array thereof such that the data can be written in the display units. The driving circuit includes a level shifter to control the supply voltage such that the thin film transistors can be opened or closed fully to write the data into the display units.

Referring to FIG. 4, a conventional level shifter 10 is shown. The level shifter includes a first p-type Metal Oxide Semiconductor (pMOS) transistor 11 and a first n-type Metal Oxide Semiconductor (nMOS) transistor 13 electrically connecting between a high voltage level VH and a low voltage level VL to form a loop. The level shifter 10 further includes a second pMOS transistor 12 and a second nMOS transistor 14 electrically connecting between the high voltage level VH and the low voltage level VL to form another loop. A drain terminal of the first pMOS transistor 11 connects with a drain terminal of the first nMOS transistor 13 and a node “a” is defined therebetween. A drain terminal of the second pMOS transistor 12 connects with a drain terminal of the second nMOS transistor 14 and a node “b” is defined therebetween. The source terminal of the first pMOS transistor 11 connects with the high voltage level VH, and the gate terminal of the first pMOS transistor 11 connects to the node “b”. The source terminal of the first nMOS transistor 13 connects with the low voltage level VL, and the gate terminal thereof serves as a first input terminal 21. The source terminal of the second pMOS transistor 12 connects with the high voltage level VH, and the gate terminal thereof connects to the node “a”. The source terminal of the second nMOS transistor 14 connects with the low voltage level VL, and the gate terminal thereof serves as a second input terminal 22. The first input terminal 21 and the second input terminal 22 are used for inputting a pair of opposite input signals respectively. That is, if the first input terminal 21 is input with a high voltage signal “1”, the second input terminal 22 is input with a opposite low voltage signal “0”; and if the first input terminal 21 is input with a low voltage signal “0”, the second input terminal 22 is input with an opposite high voltage signal “1”. The node “b” further serves as an output terminal 31 to output a voltage signal.

In operation, when the first input terminal 21 is input with the high voltage signal “1” and the second input terminal 22 is input with the low voltage signal “0”, the first nMOS transistor 13 opens and the second nMOS transistor 14 closes, thereby the low voltage level VL is transmitted to the node a. Then, the second pMOS transistor 12 opens thereby the high voltage level VH is transmitted to the node b. The first pMOS transistor 11 closes and the output terminal 31 outputs the high voltage level VH since the voltage level is transmitted to the node b.

On the contrary, when the first input terminal 21 is input with a low voltage signal “0” and the second input terminal 22 is input with a high voltage signal “1”, the second nMOS transistor 14 opens and the first nMOS transistor 13 closes thereby the low voltage level VL is transmitted to the node b. Then the first pMOS transistor 11 opens such that the high voltage level VH is transmitted to the node a. The second pMOS transistor 12 closes and the output terminal 31 output the low voltage level VL.

However, when the input signal applied to the first input terminal 21 jumps from the low voltage signal “0” to the high voltage signal “1” and the opposite input signal applied to the second input terminal 22 jumps from the high voltage signal “1” to the low voltage signal “0”, the first nMOS transistor 13 opens rapidly and the second nMOS transistor 14 closes rapidly. However, the first pMOS transistor 11, which opens when the first input terminal 21 is input with the low voltage signal “0”, does not closes instantly, resulting that the high voltage level VH, the first pMOS transistor 11, the first nMOS transistor 13 and the low voltage level VL form a loop, and the high voltage level VH continues to charges the loop for maintaining the high voltage level of the node a and the low voltage level VL begins to discharge the loop for decreasing the voltage level of the node a. Only when the voltage level of the node a is decreased under the threshold voltage of the second pMOS transistor 12, the second pMOS transistor 12 opens, and the voltage level of the node b is increased to close the first pMOS transistor 11 since the second nMOS transistor 14 closes. After the first pMOS transistor 11 closes, the voltage level of the node a is decreased to the low voltage level VL, and the voltage level of the node b is increased to the high voltage level VH. Therefore, the first pMOS transistor 11 greatly influences the output high voltage level VH of the output terminal 31 and delays the whole circuit.

Furthermore, if the first pMOS transistor 11 has an opening resistance less than that of the first nMOS transistor 13, the voltage level of the node a is difficult to be decreased to lower than the threshold voltage of the second pMOS transistor 12 to open the second pMOS transistor 12. Instantly, the voltage level of the node b cannot be increased since the second pMOS transistor 12 does not open, and the pMOS 11 cannot close, therefore the level shifter 10 does not work correctly. Therefore the level shifter 10 must be strict with the opening resistances of the first pMOS transistor 11 and the first nMOS transistor 13.

Similarly, when the input signal inputting the first input terminal 21 jumps from the high voltage signal “1” to the low voltage signal “0” and the opposite input signal inputting the second input terminal 22 jumps from the low voltage signal “0” to the high voltage signal “1”, the first nMOS transistor 13 closes rapidly and the second nMOS transistor 14 opens rapidly. At the same time, the second pMOS transistor 12, which opens when the second input terminal 22 is input the low voltage signal “0”, does not closes at once such that the high voltage level VH, the second pMOS transistor 12, the first nMOS transistor 13 and the low voltage level VL form another loop, and the high voltage level VH continues to charges the loop for maintaining the high voltage level of the node b and the low voltage level VL begins to discharge the loop for decreasing the voltage level of the node b. Only when the voltage level of the node b is decreased under the threshold voltage of the first pMOS transistor 11, the first pMOS transistor 11 opens, and the voltage level of the node a is increased to close the second pMOS transistor 12. At this time, the output terminal 31 outputs the low voltage level VL.

What is needed, therefore, is a level shifter having a higher operating speed.

### SUMMARY OF THE INVENTION

A level shifter according to a preferred embodiment, includes a first transistor, a second transistor, a third transistor, a fourth transistor, a fifth transistor, and a sixth transistor. The first and second transistors are first-type transistors; and the third and fourth transistors are second-type transistors different from the first-type transistors. The drain terminal of the first transistor connects with the drain terminal of the third transistor and a first node is defined therebetween. The drain terminal of the second transistor connects with the drain terminal of the fourth transistor and a second node is defined therebetween. The gate terminal of the first transistor connects with the second node and the gate terminal of the second transistor connects with the first node. The source terminal of the third transistor connects with a first voltage level, and the gate terminal of the third transistor receives a first input signal. The source terminal of the fourth transistor connects with the first voltage level and the gate terminal of the fourth transistor receives a second input signal opposite to the first input signal. At least one of the first node and the second node serve as output terminals of the level shifter. The fifth and sixth transistors are first-type transistors same to the first and second transistors. The drain terminal of the fifth transistor connects with the source terminal of the first transistor, the source terminal of the fifth transistor connects with a second voltage level, and the gate terminal of the fifth transistor receives the first input signal. The drain terminal of the sixth transistor connects with the source terminal of the second transistor, the source terminal of the sixth transistor connects with the second voltage level, and the gate terminal of the fifth transistor receives the second input signal.

The present level shifter employs the fifth transistor and the sixth transistor eliminates the delays made by the first transistor and the second transistor respectively, and the output voltage signal of the output terminal can change rapidly between the first voltage level and the second voltage level. Therefore, the level shifter has a quick operating speed. Furthermore, since the first transistor and the second transistor cannot influence the level shifter, the level shifter need not be strict with the opening resistances of the first transistor and the second transistor.

Other advantages and novel features of the present invention will become more apparent from the following detailed description of preferred embodiment when taken in conjunction with the accompanying drawings.

### BRIEF DESCRIPTION OF THE DRAWINGS

Many aspects of the present level shifter can be better understood with reference to the following drawings. The components in the drawings are not necessarily to scale, the emphasis instead being placed upon clearly illustrating the principles of the present level shifter. Moreover, in the drawings, like reference numerals designate corresponding parts throughout the several views.

FIG. 1 is a schematic view of a level shifter according to a first preferred embodiment of the present invention;

FIG. 2 is a schematic view of a level shifter according to a second preferred embodiment of the present invention;

FIG. 3 is a schematic view of a multi-stage level shifter according to a third preferred embodiment of the present invention; and

FIG. 4 is a schematic view of a conventional level shifter.

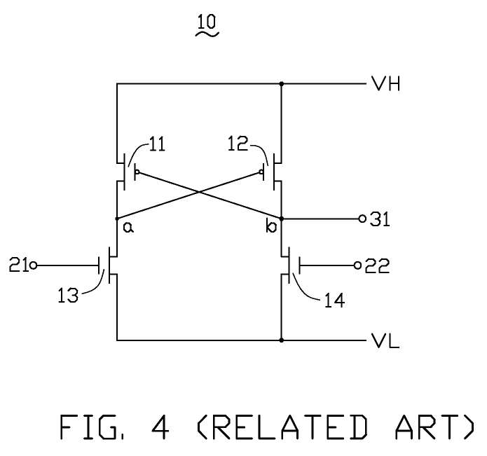

### DETAILED DESCRIPTION OF THE INVENTION

Reference will now be made to the drawings to describe a preferred embodiment of the present level shifter in detail.

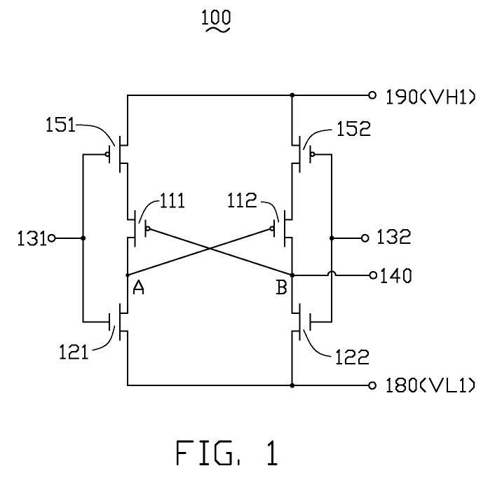

Referring to FIG. 1, a level shifter 100 in accordance with a first preferred embodiment, includes a first transistor 111, a second transistor 112, a third transistor 121, and a fourth transistor 122. The first and second transistors 111, 112 are first-type transistors, and the third and fourth transistors 121, 122 are second-type transistors different from the first-type transistors. In this exemplary embodiment, the first and second transistors 111, 112 are pMOS transistors and the third and fourth transistors 121, 122 are nMOS transistors.

The drain terminal of the first transistor 111 connects with the drain of the third transistor 121 and a node A is defined therebetween. The drain terminal of the second transistor 112 connects with the drain of the fourth transistor 122 and a node B is defined therebetween. The source terminal of the third transistor 121 connects with a first voltage level 180, and the gate terminal connects with a first input terminal 131 to receive a first input signal. In this exemplary embodiment, the first voltage level 180 is a low voltage level VL1. The source terminal of the fourth transistor 122 connects with the first voltage level 180, and the gate terminal connects with a second input terminal 132 to receive a second input signal. The first input signal is opposite to the second input signal, that is, if the first input terminal 131 is input a low voltage signal “0”, the second input terminal 132 is input a high voltage signal “1”; and if the first input terminal 131 is input the high voltage signal “1”, the second input terminal 132 is input the low voltage signal “0”. The gate terminal of the first transistor 111 connects with the node B, and the gate terminal of the second transistor 112 connects with the node A. At least one of the node A and the node B serve as output terminals. In this exemplary embodiment, the node B serves as an output terminal 140.

The level shifter 100 further includes a fifth transistor 151 and a sixth transistor 152. The fifth and sixth transistors 151, 152 are first-type transistors same to the first and second transistors 111, 112. In this exemplary embodiment, the fifth and sixth transistor 151, 152 are pMOS transistors. The drain terminal of the fifth transistor 151 connects with the source terminal of the first transistor 111, the source terminal connects with a second voltage level 190, and the gate terminal connects with the first input terminal 131 to receive the first input signal. The drain terminal of the sixth transistor 152 connects with the source terminal of the second transistor 112, the source terminal connects with the second voltage level 190, and the gate terminal connects with the second input terminal 132 to receive the second input signal. In this exemplary embodiment, the second voltage level 190 is a high voltage level VH1.

In operation, when the first input terminal 131 is input the high voltage signal “1” and the second input terminal 132 is input the low voltage signal “0”, the third transistor 121 (nMOS transistor) opens, the fourth transistor 122 (nMOS transistor) closes, the fifth transistor 151 (pMOS transistor) closes, and the sixth transistor 152 (pMOS transistor) opens such that the first voltage level 180 (low voltage level VL1) is transmitted to the node A. Since the node A has the low voltage level VL1, the second transistor 112 (pMOS transistor) opens. The second voltage level 190 (high voltage level VH1) is transmitted to the node B since the second transistor 112 and the sixth transistor 152 opens, and the first transistor 111 (pMOS transistor) closes. The output terminal 140 outputs the high voltage level VH1.

On the contrary, when the first input terminal 131 is input the low voltage signal “0” and the second input terminal 132 is input the high voltage signal “1”, the third transistor 121 (nMOS transistor) closes, the fourth transistor 122 (nMOS transistor) opens, the fifth transistor 151 (pMOS transistor) opens, and the sixth transistor 152 (pMOS transistor) closes such that the first voltage level 180 (low voltage level VL1) is transmitted to the node B. Since the node B has the low voltage level VL1, the first transistor 111 (pMOS transistor) opens. The second voltage level 190 (high voltage level VH1) is transmitted to the node A since the first transistor 111 and the fifth transistor 151 opens, and the second transistor 112 (pMOS transistor) closes. The output terminal 140 outputs the low voltage level VL1.

Furthermore, when the first input signal inputting the first input terminal 131 jumps from the low voltage signal “0” to the high voltage signal “1” and the opposite second input signal inputting the second input terminal 132 jumps from the high voltage signal “1” to the low voltage signal “0”, the third transistor 121 (nMOS transistor) opens rapidly, the fourth transistor 122 (nMOS transistor) closes rapidly, the fifth transistor 151 (pMOS transistor) closes rapidly, and the sixth transistor 152 (pMOS transistor) opens rapidly. Since the fifth transistor 151 (pMOS transistor) closes rapidly, the second voltage level 190 (high voltage level VH1), the fifth transistor 151, the first transistor 111, the third transistor 121, and the first voltage level 180 (low voltage level VL1) cannot form a loop such that the second voltage level 190 (high voltage level VH1) cannot continues to charge the node A. At this time, only the first voltage level 180 (low voltage level VL1) discharges the node A rapidly since the third transistor 121 opens, and the first transistor 111 which may be opened at this time, cannot influence the voltage level of the node A. Therefore, the voltage level of the node A can be decreased rapidly to the first voltage level 180 (low voltage level VL1) such that the second transistor 112 (pMOS transistor) can open rapidly. The voltage level of the node B can be increased rapidly to the second voltage level 190 (high voltage level VH1) since the sixth transistor 152 and the second transistor 112 open rapidly and the fourth transistor 122 closes rapidly. That is, the output terminal 140 can output the second voltage level 190 (high voltage level VH1) rapidly.

Similarly, when the first input signal inputting the first input terminal 131 jumps from the high voltage signal “1” to the low voltage signal “0” and the opposite second input signal inputting the second input terminal 132 jumps from the low voltage signal “0” to the high voltage signal “1”, the fourth transistor 122 (nMOS transistor) opens rapidly and the sixth transistor 152 (pMOS transistor) closes rapidly. Since the sixth transistor 152 closes rapidly, the second voltage level 190 (high voltage level VH1), the sixth transistor 152, the second transistor 112, the fourth transistor 122 and the first voltage level 180 (low voltage level VL1) cannot form a loop such that the second voltage level 190 (high voltage level VH1) cannot charge the node B, and only the first voltage level 180 (low voltage level VL1) discharge the node B. Therefore, the voltage level of the node B can be decreased rapidly to the low voltage level VL1. The second transistor 112 which may be opened at this time, cannot influence the voltage level of the node B.

Comparing with the conventional level shifter, the present level shifter 100 uses the fifth transistor 151 (pMOS transistor) and the sixth transistor 152 (pMOS transistor) to eliminate the delays made by the first transistor 111 (pMOS transistor) and the second transistor 112 (pMOS transistor) respectively, and the output voltage signal of the output terminal 140 can be increased rapidly from the low voltage level VL1 to the high voltage level VH1 or be decreased rapidly from the high voltage level VH1 to the low voltage level VL1. Therefore, the level shifter 100 has a quick operating speed. Furthermore, since the first transistor 111 and the second transistor 112 cannot influence the level shifter 100, the level shifter 100 need not be strict with the opening resistances of the first transistor 111 and the second transistor 112. The level shifter 100 has a small current and the power consumed is low.

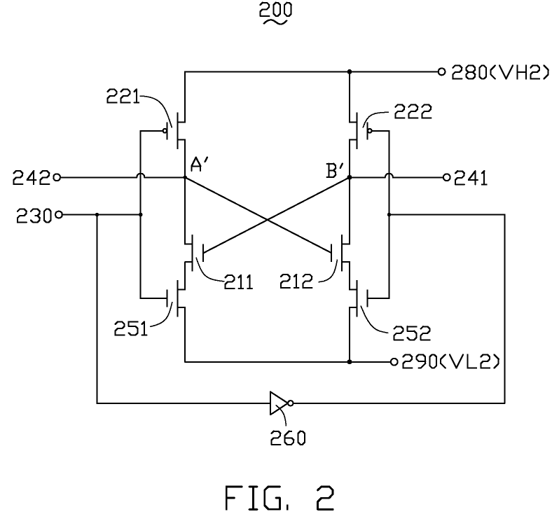

Referring to FIG. 2, a level shifter 200 in accordance with a second preferred embodiment, is shown. The level shifter 200 is similar to that of the first preferred embodiment, except that the first and second transistors 211, 212 are nMOS transistors and the third and fourth transistors 221, 222 are pMOS transistors. The fifth and sixth transistors 251, 252 are nMOS transistors same as the first and second transistors 211, 212. The first voltage level 280 is a high voltage level VH2, and the second voltage level 290 is a low voltage level VL2. The level shifter 200 includes only one input terminal 230 and two output terminals 241, 242. The input terminal 230 connects with the gate terminal of the third transistor 221 and the gate terminal of the fifth transistor 251 for supplying an input signal to drive the third and fifth transistors 221, 251; and the input terminal 230 connects with the gate terminal of the fourth transistor 222 and the gate terminal of the sixth transistor 252 through an inverter 260 for supplying an opposite input signal to drive the fourth and sixth transistors 222, 252. The first output terminal 242 connects with a node A′ defined between the drain terminal of the first transistor 211 and the drain terminal of the third transistor 221 for output a first output signal; and the second output terminal 241 connects with a node B′ defined between the drain terminal of the second transistor 212 and the drain terminal of the fourth transistor 222 for output a second output signal opposite to the first output signal.

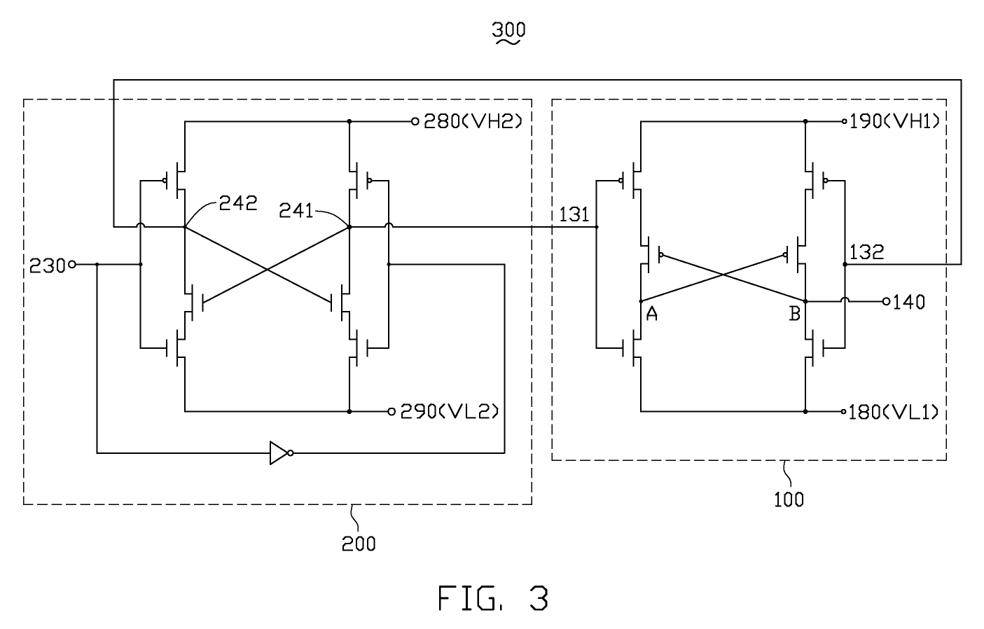

Referring to FIG. 3, a multi-stage level shifter 300 in accordance with a third preferred embodiment, is shown. The level shifter 300 is a two-stage level shifter, and includes two level shifter 100, 200 described in the first and second preferred embodiment. The first output terminal 241 of the level shifter 200 connects with the first input terminal 131 of the level shifter 100, and the second output terminal 242 of the level shifter 200 connects with the second input terminal 132 of the level shifter 100. The input terminal 230 of the level shifter 200 serves as the input terminal of the level shifter 300, and the output terminal 140 of the level shifter 100 serves as the output terminal of the level shifter 300.

In this exemplary embodiment, the first-type transistors of the level shifter 200 are nMOS transistors, and the second-type transistors are pMOS transistors; the first-type transistors of the level shifter 100 are pMOS transistors and the second-type transistors are nMOS transistors. The first voltage level 280 of the level shifter 200 is a first high voltage level VH2, and the second voltage level 290 is a first low voltage level VL2; the first voltage level 180 of the level shifter 100 is a second low voltage level VL1 and the second voltage level 190 is a second high voltage level VH1. The first high voltage level VH2 of the level shifter 200 is lower than the second high voltage level VH1 of the level shifter 100. The first low voltage level VL2 of the level shifter 200 is higher or equal to the second low voltage level VL1 of the level shifter 100.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A level shifter, comprising:
a first transistor;
a second transistor, the first and second transistors being first-type transistors;
a third transistor;
a fourth transistor, the third and fourth transistors being second-type transistors different from the first-type transistors, the drain terminal of the first transistor connecting with the drain terminal of the third transistor and a first node defining therebetween, the drain terminal of the second transistor connecting with the drain terminal of the fourth transistor and a second node defining therebetween, the gate terminal of the first transistor connecting with the second node and the gate terminal of the second transistor connecting with the first node, the source terminal of the third transistor connecting with a first voltage level, and the gate terminal of the third transistor receiving a first input signal, the source terminal of the fourth transistor connecting with the first voltage level and the gate terminal of the fourth transistor receiving a second input signal opposite to the first input signal, at least one of the first node and the second node serving as output terminals of the level shifter;
a fifth transistor; and
a sixth transistor, the fifth and sixth transistors being first-type transistors same as the first and second transistors, the drain terminal of the fifth transistor connecting with the source terminal of the first transistor, the source terminal of the fifth transistor connecting with a second voltage level, and the gate terminal of the fifth transistor receiving the first input signal, the drain terminal of the sixth transistor connecting with the source terminal of the second transistor, the source terminal of the sixth transistor connecting with the second voltage level, and the gate terminal of the fifth transistor receiving the second input signal.

2. The level shifter as claimed in claim 1, wherein the first-type transistors are pMOS transistors, and the second-type transistors are nMOS transistors.

3. The level shifter as claimed in claim 2, wherein the first voltage level is a low voltage level and the second voltage level is a high voltage level.

4. The level shifter as claimed in claim 1, wherein the first-type transistors are nMOS transistors, and the second-type transistors are pMOS transistors.

5. The level shifter as claimed in claim 4, wherein the first voltage level is a high voltage level and the second voltage level is a low voltage level.

6. The level shifter as claimed in claim 1, further comprising a first input terminal for supplying the first input signal and a second input terminal for supplying the second input signal opposite to the first input signal.

7. The level shifter as claimed in claim 1, further comprising an input terminal for supplying one of the first input signal and the opposite second input signal, and an inverter connecting with the input terminal for supplying another opposite signal.

8. A multi-stage level shifter, comprising
a first level shifter claimed as claim 1; and
a second level shifter claimed as claim 1, the voltage level of the first node of the first level shifter serving as the second input signal of the second level shifter, and the voltage level of the second node of the first level shifter serving as the first input signal of the second shifter.

9. The multi-stage level shifter as claimed in claim 8, wherein the first-type transistors of the first level shifter are nMOS transistors, and the second-type transistors are pMOS transistors; the first-type transistors of the second level shifter are pMOS transistors and the second-type transistors are nMOS transistors.

10. The multi-stage level shifter as claimed in claim 9, wherein the first voltage level of the first level shifter is a first high voltage level, and the second voltage level is a first low voltage level; the first voltage level of the second level shifter is a second low voltage level and the second voltage level is a second high voltage level.

11. The multi-stage level shifter as claimed in claim 10, wherein the first high voltage level of the first level shifter is lower than the second high voltage level of the second level shifter.

12. The multi-stage level shifter as claimed in claim 10, wherein the first low voltage level of the first level shifter is higher than the second low voltage level of the second level shifter.

13. The multi-stage level shifter as claimed in claim 10, wherein the first low voltage level of the first level shifter is equal to the second low voltage level of the second level shifter.
